(19) United States
(12) Patent Application Publication
(10) Pub. No.: US 2021/0384407 A1
(43) Pub. Date: Dec. 9, 2021

(54) PINNING CENTER INTRODUCTION DEVICE, PINNING CENTER INTRODUCTION METHOD AND SUPERCONDUCTOR TAPE

(71) Applicant: Shanghai Superconductor Technology Co. LTD, Shanghai (CN)

(72) Inventors: GUANGYU JIANG, Shanghai (CN); YUE ZHAO, Shanghai (CN); JIAMIN ZHU, Shanghai (CN); ZHONGHE GAO, Shanghai (CN)

(21) Appl. No.: 17/039,600

(22) Filed: Sep. 30, 2020

(30) Foreign Application Priority Data
Jun. 5, 2020 (CN) 202010507795.0

(51) Int. Cl. H01L 39/24; H01B 12/06

(52) U.S. Cl. CPC H01L 39/2483; H01B 12/06

(57) ABSTRACT

The present invention provides a pinning center introduction device, a pinning center introduction method and a superconductor tape. The pinning center introduction device includes a bending shaft and a heating zone. The bending shaft is arranged in the heating zone. The superconductor tape is arranged around the bending shaft. The heating zone keeps the superconductor tape entering the heating zone and the bending shaft at a target temperature. The superconductor tape is bent on the bending shaft to obtain strain, so that a micro-structure of a superconducting film is reconstructed under the action of the strain and the target temperature.

### CROSS-REFERENCE TO RELATED APPLICATIONS

This application claims the benefit of priority from Chinese Patent Application No. 202010507795.0, filed on Jun. 5, 2020. The content of the aforementioned applications, including any intervening amendments thereto, is incorporated herein by reference.

### TECHNICAL FIELD

The present invention relates to the field of superconductor tapes, in particular to a pinning center introduction device, a pinning center introduction method and a superconductor tape.

### BACKGROUND OF THE PRESENT INVENTION

Second-generation high-temperature superconductor (2G-HTS) tapes refer to materials obtained by rare-earth barium cuprates or yttrium barium cuprates based films grown on a flexible substrate. With the advantages of high critical transition temperature, high current-carrying capacity and high irreversibility field, 2G-HTS tapes are widely applied in a wide temperature range and magnetic field range for various applications, such as transmission cables, fault current limiter, inductive heater, wind mill, high-field magnets, etc. Among them, a superconducting magnet is one of the most promising application. With the continuous development of the superconducting magnet technology, more requirements of detailed and higher performance for 2G-HTS tapes have been proposed For example, further improvement of the in-field current-carrying capacity, and further reduction of the superconductivity anisotropy are important issues to be solved to promote the practical applications of 2G-HTS tapes.

For 2G-HTS materials, introducing flux pinning centers is the main approach to improve in-field current-carrying capacity. The so-called flux pinning centers refer to defects in various geometries and dimensions (nanometers to submicrometers) which are capable of restricting the motion of flux lines and preventing the “flux creep”. Some common pinning centers include: atomic substitutions, holes, dislocations, second phases, grain boundaries, twin crystals and so on. Generally, there are two methods for introducing pinning centers, i.e., a bottom-up method and a top-down method. The bottom-up method refers to introducing the defects as pinning centers in the deposition process of superconducting films. A most representative example is to perform doping in the superconducting films to generate a self-assembled nanoscale second phase with a fine nano-structure in the deposition process. The top-down method refers to introducing other physical fields to generate certain defects in the superconducting film as pinning centers after the deposition of superconducting films. There are fewer reports about the top-down method. One successful example is to apply high-flux neutron radiation to bring defects in the superconducting film.

The above two pinning center introduction methods have their own features. The bottom-up method could introduce effective pinning and has already been widely studied, but challenges still remain in the industrialization process: the fine nano-structure of such second phase requires an extremely-low deposition rate, so it is difficult to obtain superconducting films with desirable microstructure under the high deposition rate of high-volume production. The top-down method is not linked to the deposition rate, but is limited to the technological conditions. So its feasibility in the high volume production is still not clear. Therefore, it is very urgent to develop an industrializable technology that does not rely on the deposition rate.

### SUMMARY OF THE PRESENT INVENTION

In order to overcome the shortcomings in the prior art, the purpose of the present invention is to provide a pinning center introduction device, a pinning center introduction method and a superconductor tape.

The pinning center introduction device suitable for high volume industrial production according to the present invention includes a bending shaft 1 and a heater with a heating zone 2.

The bending shaft 1 is arranged in the heating zone 2, and a superconductor tape 3 is winded on the circumference of the bending shaft 1.

The heating zone 2 is used to heat the superconductor tape 3 and the bending shaft 1 which is located inside the heating zone 2 and to keep the superconductor tape 3 and the bending shaft 1 at a target temperature. Preferably, the superconductor tape 3 is wound around the bending shaft 1. The superconductor tape 3 is pulled by an external force to leave the heating zone 2.

Preferably, the bending shaft 1 can rotate around the center axis of the bending shaft 1.

Preferably, the target temperature ranges from 200° C. to 900° C.

Preferably, the superconductor tape 3 has a compressive side 31 and a tensile side 32 when in bending. A superconducting film of the superconductor tape 3 is located at the compressive side 31 and/or the tensile side 32.

Preferably, the superconductor tape 3 is wound around the bending shaft 1 in a “U” shape or a helical shape.

The pinning center introduction method according to the present invention utilizes the above pinning center introduction device to introduce the pinning centers to the superconductor tape 3.

Preferably, the superconductor tape 3 is wound around the bending shaft 1 with different radii to obtain different strains.

The superconductor tape 3 according to the present invention is prepared by the above pinning center introduction method.

Compared with the prior art, the present invention has the following beneficial effects:

1. By utilizing the top-down pinning center introduction method, the generation process of the pinning centers is not related to the deposition rate, thereby being suitable for the high volume industrial production. Furthermore, the implementation process is simple and efficient and requires no complicated device and process control.

2. The defects generated by utilizing the method of the present invention are mainly dislocations parallel to the a-b plane of rare-earth barium cuprates or yttrium barium cuprates, which can effectively reduce the superconductivity anisotropy in the superconductor material, thereby being conducive to the application of the superconductor tape in superconductor magnets.

3. The present invention can significantly improve the in-field current-carrying capacity of the 2G-HTS tape, and is suitable for various preparation methods (such as pulsed laser deposition, chemical vapor deposition, chemical solution deposition, etc.), and the superconductor tapes with various components (rare-earth barium cuprates compounds or yttrium barium cuprates compounds that are doped or undoped with various elements).

### BRIEF DESCRIPTION OF THE DRAWINGS

By reading the detailed description of the non-limited embodiments with reference to the following drawings, other features, purposes and advantages of the present invention may become more apparent:

FIG. 1 is a structural schematic diagram of a typical 2G-HTS tape; and

FIG. 2 is a structural schematic diagram of a pinning center introduction device of the present invention.

### DETAILED DESCRIPTION OF THE PRESENT INVENTION

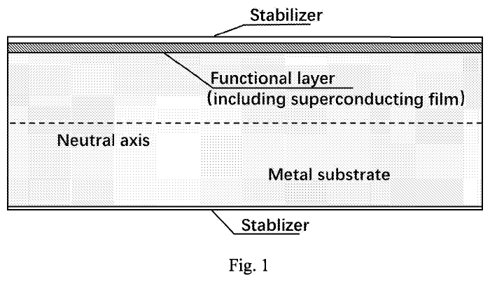

The present invention is described in detail below in combination with embodiments. The following embodiments may help those skilled in the art to further understand the present invention but do not limit the present invention in any form. It should be pointed out that various modifications and improvements may be made by those skilled in the art without departing from the concept of the present invention. These modifications and improvements belong to the protection scope of the present invention. FIG. 1 shows a structure of a typical 2G-HTS tape. A functional layer includes a rare-earth barium cuprates compound layer, a buffer layer, a seed layer and a cap layer; or the functional layer includes an yttrium barium cuprates compound layer, a buffer layer, a seed layer and a cap layer. The rare-earth barium cuprates compound layer or the yttrium barium cuprates compound layer is a superconducting film. The functional layer is deposited on a metal substrate. In some fields, the functional layer may also be covered with a stable layer such as metal silver. In the entire second-generation high-temperature superconductor tape, due to the requirement of mechanical properties, the metal substrate occupies most of a thickness of the entire second-generation high-temperature superconductor tape.

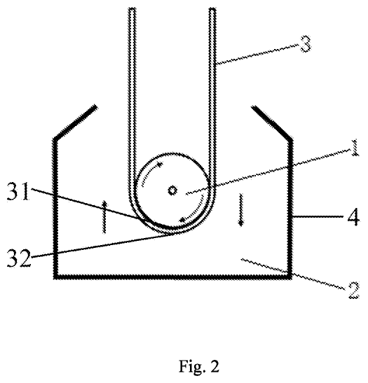

As shown in FIG. 2, the pinning center introduction device provided by the present invention is suitable for the high volume industrial production. The pinning center introduction device includes a bending shaft 1 and a heater 4 with a heating zone 2. The bending shaft 1 is arranged in the heating zone 2. The superconductor tape 3 is arranged around the bending shaft 1. The heating zone 2 is used to heat the superconductor tape 3 and the bending shaft 1 located in the heating zone 2 and to keep the superconductor tape 3 and the bending shaft 1 at a target temperature. The superconductor tape 3 is bent on the bending shaft 1 to obtain strain. Under the action of the strain and target temperature, a micro-structure of the superconducting film of the superconductor tape 3 is reconstructed.

The superconductor tape 3 may be a tape without introduced pinning centers, and may also be the tape introducing various forms of pinning centers through other methods.

When the superconductor tape 3 is bent, the superconductor tape is divided into an upper portion and a lower portion by taking a geometric center of the entire superconductor tape 3 in a thickness direction as a dividing line (named a neutral axis). The upper portion of the superconductor tape 3 generates the compressive strain, and one side generating the compressive strain is a compressive side 31. The compressive side 31 is one side of the superconductor tape 3 facing the bending shaft 1. The lower portion of the superconductor tape 3 generates the tensile strain, and one side generating the tensile strain is a tensile side 32. The tensile side 32 is one side of the superconductor tape 3 back to the bending shaft 1. The superconductor tape 3 arranged around the bending shaft 1 with different radii may be bent in different degrees, so that the superconducting film of the superconductor tape 3 may be subjected to the changeable and controllable compressive or tensile strain. The strain may induce the reconstruction of the micro-structure of the superconducting film to generate the defects such as dislocations, stacking faults and the like, thereby improving the pinning performance of the superconducting film, and improving the in-field current-carrying capacity of the superconductor tape 3.

It should be noted that the reconstruction of the micro-structure of the superconducting film may be limited by the dynamics of the material at the normal temperature, and the reconstruction process is very slow, which needs to change the temperature to accelerate the reconstruction process. When the superconductor tape 3 is bent, the superconductor tape 3 may be heated, and an optional temperature ranges from 200° C. to 900° C. Under the action of the high temperature, the atom mobility is apparently improved, the reconstruction process of the micro-structure of the superconducting film is greatly accelerated, and the required time is reduced exponentially. This makes the application of the strain-induced defects in the high volume industrial production more operable.

The superconductor tape 3 is wound around the bending shaft 1. The superconductor tape 3 is pulled by an external force to leave the heating zone 2. Specifically, one end of the superconductor tape 3 enters the heating zone 2 and is wound around the bending shaft 1. Thereafter, one end of the superconductor tape 3 is pulled by the external force to leave the heating zone 2. In this process, the entire superconductor tape 3 gradually enters the heating zone 2 to be wound around the bending shaft 1 and gradually leaves the heating zone 2 under the pulling of the external force. The heating time of the superconductor tape 3 in the heating zone 2 is controlled by the moving speed of the superconductor tape 3. The bending shaft 1 is designed to be able to rotate around the center axis of the bending shaft 1, which is used to reduce the frictional force in the moving process of the superconductor tape 3. The superconductor tape 3 may be wound around the bending shaft 1 in a U shape at one time or wound around the bending shaft 1 in a spiral shape at multiple times.

By taking FIG. 2 as an example, when the superconductor tape 3 is pulled by the external force, since the superconductor tape 3 is wound around the bending shaft 1, the superconductor tape 3 is in a bent state, thereby further making the superconducting film obtain the strain. According to the orientation of the superconductor tape 3 relative to the bending shaft 1, the superconducting film can obtain the compressive or tensile strain. According to the needed strain, the bending shaft 1 can select various radii. By taking FIG. 2 as an example, the bending shaft 1 is located in the heating zone 2. The heating zone 2 is used to heat the superconductor tape 3 and the bending shaft 1, which keeps the superconductor tape 3 and the bending shaft 1 at a target temperature. According to different defect densities required by the superconductor tape 3, the reconstruction time of the micro-structure of the superconducting film is different. When the superconductor tape 3 is under different strains and different temperatures, the reconstruction time of the micro-structure of the superconducting film is also different. On this basis, the heating time of the superconductor tape 3 in the heating zone 2 can be controlled by controlling the moving speed of the superconductor tape 3. Therefore, the reconstruction process can be fully completed by adjusting the moving speed of the superconductor tape 3 in the heating zone 2.

The present invention also provides a pinning center introduction method, which utilizes the above pinning center introduction device to introduce the pinning centers to the superconductor tape 3. At the same time, the present invention also provides a superconductor tape 3, which is prepared by using the above pinning center introduction method; or the superconductor tape may also be a second-generation high-temperature superconductor tape.

The comparison of parameters of the superconductor tape 3 prepared by the method of the present invention and by the conventional method is shown in table I. When components and other coating parameters are the same, the method of the present invention has obvious advantages. By using the top-down pinning center introduction method, the deposition rate of the superconductor tape 3 is completely unlimited. The deposition rate is tens of times or more of that of the traditional method. Meanwhile, due to the reconstruction of the micro-structure of a superconducting film, a large number of stacking faults with extremely high density is introduced into the superconducting film. Under such high deposition rate, no second phase with fine nanostructure, for example, nanocolumn, can be generated, and the excellent pinning performance is still obtained through the high-density stacking faults, so that the prepared superconductor tape 3 has good in-field current-carrying capacity.

TABLE 1
Comparison of deposition parameters and performances of the present
invention and the traditional pinning center introduction method

| | Strain-induced | Nano structure |
|---|---|---|
| Pinning center | reconstruction of the | formed by in- |
| introduction method | micro-structure | situ deposition |
| Bending radius (mm) | 6 mm | — |
| Heating temperature (° C.) | 600 | — |
| Average deposition rate | 100 | 2-3 |
| (nm/s) | | |
| Main pinning type | Stacking faults | Nanocolumns |
| Density of stacking faults | >0.01 | 0.0001 |
| (nm⁻³) | | |
| Pinning force@4.2K, 10 T | 1000 | 800 |
| (GN/m³) | | |
| Ic@4.2K, 10 T (A/cm-w) | >1500 | −1000 |

In the description of the present application, it should be noted that the terms “upper,” “lower,” “front,” “rear,” “left,” “right”, “vertical”, “horizontal”, “top”, “bottom”, “inside”, “outside”, and the like indicating the orientation or positional relationship are based on the orientation or positional relationship shown in the drawings, and are only used for convenience in describing the present application and simplifying the description, rather than indicating or implying that specific devices or elements must have a specific orientation and be constructed and operated in a specific orientation. Therefore, the terms shall not be understood as limitations to the present application.

The specific embodiments of the present invention are described above. It should be understood that the present invention is not limited to the specific embodiments. Those skilled in the art can make various modifications or changes within the scope of the claims without influencing the substantive content of the present invention. In case of no conflict, the embodiments of the present application and the features in the embodiments can be combined randomly.

We claim:

1. A pinning center introduction device, comprising a bending shaft (1) and a heater (4) with a heating zone (2), wherein
the bending shaft (1) is arranged in the heating zone (2), and the periphery of the bending shaft (1) is used for winding a superconductor tape (3);
the heating zone (2) is used to heat the superconductor tape (3) and the bending shaft (1) located in the heating zone (2), and to keep the superconductor tape (3) and the bending shaft (1) at a target temperature.

2. The pinning center introduction device according to claim 1, wherein the superconductor tape (3) is wound around the bending shaft (1); and the superconductor tape (3) is pulled by an external force to leave the heating zone (2).

3. The pinning center introduction device according to claim 1, wherein the bending shaft (1) can rotate around the center axis of the bending shaft (1).

4. The pinning center introduction device according to claim 1, wherein the target temperature ranges from 200° C. to 900° C.

5. The pinning center introduction structure according to claim 1, wherein the superconductor tape (3) has a compressive side (31) and a tensile side (32) when in bending; and a superconducting film of the superconductor tape (3) is located at the compressive side (31) and/or the tensile side (32).

6. The pinning center introduction structure according to claim 1, wherein the superconductor tape (3) is wound around the bending shaft (1) in a “U” shape or a helical shape.

7. A pinning center introduction method, utilizing the pinning center introduction structure of claim 1 to introduce the pinning centers to the superconductor tape (3).

8. The pinning center introduction method according to claim 7, wherein the superconductor tape (3) is wound around the bending shaft (1) with different radii to obtain different strains.

9. A superconductor tape, prepared by the pinning center introduction method of claim 7.
